(19) United States
(12) Patent Application Publication
(10) Pub. No.: US 2026/0068761 A1
(43) Pub. Date: Mar. 5, 2026

(54) SEMICONDUCTOR PACKAGE

(71) Applicant: Samsung Electronics Co., Ltd., Suwon-si (KR)

(72) Inventors: Daewoong Heo, Suwon-si (KR); Gihwan Kim, Suwon-si (KR)

(21) Appl. No.: 19/180,937

(22) Filed: Apr. 16, 2025

(30) Foreign Application Priority Data
Aug. 28, 2024 (KR) 10-2024-0116001

(51) Int. Cl. H01L 25/07; H01L 23/31; H01L 23/538

(52) U.S. Cl. CPC H01L 25/071

(57) ABSTRACT

A semiconductor package including a printed circuit board, a plurality of semiconductor chips arranged apart from the printed circuit board in a vertical direction and a plurality of bonding wires. Each of the bonding wires including a first end in contact with the printed circuit board, and a second end in contact with a chip pad included in each of the plurality of semiconductor chips. The semiconductor package further including a first encapsulation layer filling spaces between lower surfaces of the plurality of semiconductor chips and an upper surface of the printed circuit board and spaces between the plurality of bonding wires, and a second encapsulation layer covering an upper surface of the first encapsulation layer and the plurality of semiconductor chips and including a flat upper surface arranged apart from the upper surface of the printed circuit board by a same height in all areas.

### CROSS-REFERENCE TO RELATED APPLICATION

This application is based on and claims priority under 35 U.S.C. § 119 to Korean Patent Application No. 10-2024-0116001, filed on Aug. 28, 2024, in the Korean Intellectual Property Office, the disclosure of which is incorporated by reference herein in its entirety.

### BACKGROUND

Aspects of the inventive concept relate to a semiconductor package. More particularly, aspects of the inventive concept relate to a semiconductor package including a printed circuit board.

According to the rapid development of the electronic industry and user demand, electronic devices have become smaller and lighter. Such miniaturization and reduction in weight of electronic devices have also rendered semiconductor packages used therein smaller and lighter, requiring high reliability of semiconductor packages. Accordingly, semiconductor chips included in a semiconductor package need to be stacked and easily connected by using a bonding wire.

### SUMMARY

Aspects of the inventive concept provide a semiconductor package in which a plurality of semiconductor chips are connected to a printed circuit board to secure economic feasibility and mechanical stability.

The object which the technical ideas of the inventive concept seek to achieve is not limited to the foregoing, and other objects may be clearly understood by a person skilled in the art from the description below.

Aspects of the inventive concept provide a semiconductor package as described below.

According to an aspect of the inventive concept, there is provided a semiconductor package including a printed circuit board, a plurality of semiconductor chips arranged apart from the printed circuit board in a vertical direction, a plurality of bonding wires, wherein a first end of each of the bonding wires is in contact with the printed circuit board, and a second end, which is opposite to the first end, is in contact with a chip pad included in each of the plurality of semiconductor chips, a first encapsulation layer filling spaces between lower surfaces of the plurality of semiconductor chips and an upper surface of the printed circuit board and spaces between the plurality of bonding wires, and a second encapsulation layer covering an upper surface of the first encapsulation layer and the plurality of semiconductor chips and including a flat upper surface arranged apart from the upper surface of the printed circuit board by a same height in all areas.

According to another aspect of the inventive concept, there is provided a semiconductor package including a printed circuit board including a first surface and a second surface facing the first surface, a plurality of semiconductor chips stacked in a stepped manner in a first horizontal direction at a vertical level higher than the first surface of the printed circuit board, a plurality of bonding wires connecting the plurality of semiconductor chips to the first surface of the printed circuit board in a vertical direction and each overlapping a conductive pad included in the printed circuit board in the vertical direction, a first encapsulation layer filling spaces between lower surfaces of the plurality of semiconductor chips and an upper surface of the printed circuit board and spaces between the plurality of bonding wires, a second encapsulation layer covering upper surfaces and lateral surfaces of the plurality of semiconductor chips stacked in the stepped manner, filling a space on the first encapsulation layer, and including a flat upper surface arranged apart from the first surface by a same height in all areas, and an external connection terminal attached onto the second surface of the printed circuit board, wherein the second encapsulation layer is in contact with the first encapsulation layer in at least some areas and is arranged apart from the first encapsulation layer with the plurality of semiconductor chips arranged therebetween in the other areas that are not in contact with the first encapsulation layer, and the first encapsulation layer and the second encapsulation layer include different materials from each other.

According to another aspect of the inventive concept, there is provided a semiconductor package including a printed circuit board including an upper surface and a lower surface and arranged at a vertical level lower than a plurality of first semiconductor chips and a plurality of second semiconductor chips, at least one first semiconductor chip stack in which the plurality of first semiconductor chips are stacked in a stepped manner in a first horizontal direction, wherein the first horizontal direction is a direction horizontal to surfaces of the plurality of first semiconductor chips and a direction in which the plurality of first semiconductor chips are stacked, a second semiconductor chip stack in which the plurality of second semiconductor chips are stacked in the stepped manner in a reverse first horizontal direction which is opposite to the first horizontal direction, wherein the reverse first horizontal direction is a direction horizontal to the plurality of second semiconductor chips and a direction in which the plurality of second semiconductor chips are stacked, a first encapsulation layer sealing a space between the upper surface of the printed circuit board and the first and second semiconductor chip stacks, a plurality of bonding wires arranged within the first encapsulation layer and connecting each of the plurality of first semiconductor chips and each of the second semiconductor chips to the printed circuit board in a vertical direction, a second encapsulation layer covering upper surfaces and lateral surfaces of the at least one first semiconductor chip stack, and the at least one second semiconductor chip stack and an upper surface of the first encapsulation layer, the second encapsulation layer including a material having a different coefficient of thermal expansion than a material included in the first encapsulation layer, and an external connection terminal attached onto the lower surface of the printed circuit board, wherein a wire diameter of each of the plurality of bonding wires is in a range from 0.7 mm to 1 mm, and a distance between an upper surface of the second encapsulation layer and the first and second semiconductor chip stacks is in a range from 50 um to 70 um.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment; and

FIGS. 2 to 9 are each a cross-sectional view partially illustrating a process of manufacturing a semiconductor package according to an embodiment.

### DETAILED DESCRIPTION OF THE EMBODIMENTS

Hereinafter, embodiments of the inventive concept are described in detail with reference to the accompanying drawings. In the drawings, like reference numerals denote like components, and any redundant description thereon will be omitted.

As aspects of the inventive concept allow for various changes and numerous embodiments, certain embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed in embodiments. In the description of embodiments certain detailed explanations of the related art are omitted when it is deemed that they may unnecessarily obscure the essence of the inventive concept.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

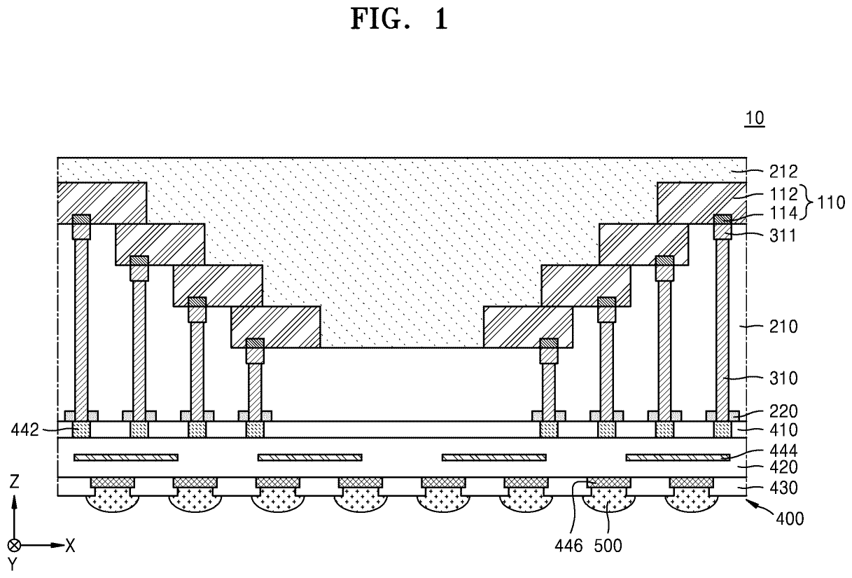

FIG. 1 is a cross-sectional view of a semiconductor package 10 according to an embodiment.

More specifically, the semiconductor package 10 may include a semiconductor chip 110, a first encapsulation layer 210, a second encapsulation layer 212, a conductive connector 220, a bonding wire 310, a printed circuit board 400, and an external connection terminal 500.

A plurality of semiconductor chips 110 may be stacked, for example, in a stepped manner in a first horizontal direction (X direction). The first horizontal direction (X direction) may be a direction horizontal to a surface of the semiconductor chip 110 and a direction in which the semiconductor chips 110 are stacked in a stepped manner.

Each semiconductor chip 110 may include a body 112 and a chip pad 114. Although it is not shown in the drawings, an adhesive layer may be included in a lower portion of the semiconductor chip 110. The adhesive layer may include an insulating adhesive material, such as die attach film (DAF). The thickness of the adhesive layer may be tens of micrometers.

The body 112 may include a semiconductor material, for example, a Group IV semiconductor material, a Group III-V semiconductor material, a Group II-VI semiconductor material, or a combination thereof. The Group IV semiconductor material may include silicon (Si), germanium (Ge), or a combination thereof. The Group III-V semiconductor material may include GaAs, InP, GaP, InAs, InSb, InGaAs, or a combination thereof. The Group II-VI semiconductor material may include ZnTe, CdS, or a combination thereof. The semiconductor chip may include an integrated circuit. The integrated circuit may be any kind of integrated circuit including a memory circuit, a logic circuit, or a combination thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. The logic circuit may include, for example, a central processing unit (CPU) circuit, a graphic processing unit (GPU) circuit, a controller circuit, an application specific integrated circuit (ASIC), an application processor (AP) circuit, or a combination thereof.

As illustrated in FIG. 1, the chip pads 114 of the semiconductor chips 110 may be arranged apart from each other in the first horizontal direction (X direction). As to be described below, the chip pad 114 may be a terminal connected to the bonding wire 310.

Although the chip pad 114 is illustrated as being present in each semiconductor chip 110, this is only an example, and a plurality of chip pads 114 arranged apart from each other may be included in one semiconductor chip 110.

In an embodiment, the first encapsulation layer 210 may seal a space between the printed circuit board 400 and the semiconductor chips 110. For example, the first encapsulation layer 210 may seal spaces arranged vertically apart from each other between exposed lower surfaces of the semiconductor chips 110 and an upper surface of the printed circuit board 400. In the specification, a vertical direction (Z direction) may be defined as a direction in which the semiconductor chips 110 are stacked and a direction perpendicular to the first horizontal direction (X direction) and a second horizontal direction (Y direction). The second horizontal direction (Y direction) may be a direction horizontal to the surfaces of the semiconductor chips 110, and the second horizontal direction (Y direction) may also be a direction perpendicular to the first horizontal direction (X direction) from the surfaces of the semiconductor chips 110.

In an embodiment, the second encapsulation layer 212 may mold all of upper surfaces and lateral surfaces of the semiconductor chips 110 arranged in a stepped manner. For example, in at least some areas, the second encapsulation layer 212 may be arranged apart from the first encapsulation layer 210 with the semiconductor chips 110 arranged therebetween. The second encapsulation layer 212 may include a material different from a material of the first encapsulation layer 210. For example, the second encapsulation layer 212 may include a material having a different thermal expansivity from the first encapsulation layer 210. As the second encapsulation layer 212 includes a material having a different thermal expansivity from the first encapsulation layer 210, the mechanical stability of a package may be secured in terms of possibility of warpage occurrence. However, as to be described below, the second encapsulation layer 212 may include the same material as the first encapsulation layer 210.

The first encapsulation layer 210 and the second encapsulation layer 212 may include, for example, thermosetting resin such as epoxy resin, thermoplastic resin such as polyimide, or resin obtained by adding inorganic fillers thereto, such as ABF, FR-4, BT, resin, etc. In addition, the first encapsulation layer 210 and the second encapsulation layer 212 may include a molding material such as epoxy molding compound (EMC) or a photosensitive material such as photo imageable encapsulant (PIE).

In some embodiments, when the first encapsulation layer 210 and the second encapsulation layer 212 include different materials from each other, a coefficient of thermal expansion of the material included in the first encapsulation layer 210 may be about 10 ppm/° C. to about 15 ppm/° C., and a coefficient of thermal expansion of the material included in the second encapsulation layer 212 may be about 2.5 ppm/° C. to about 6 ppm/° C.

In some embodiments, when the first encapsulation layer 210 and the second encapsulation layer 212 include different materials from each other, a thermal conductivity of the material included in the first encapsulation layer 210 may be about 1.8 W/mK to about 3 W/mK, and a thermal conductivity of the material included in the second encapsulation layer 212 may be about 1.5 W/mK to about 2 W/mK.

The printed circuit board 400 may include a first photoresist layer 410, an insulating layer 420, a second photoresist layer 430, a conductive pad 442 buried in the first photoresist layer 410, a conductive pattern 444 buried in the insulating layer 420, and an external connection pad 446 buried in the second photoresist layer 430.

The first photoresist layer 410 may be arranged along a lower surface of the first encapsulation layer 210. Areas of the lower surface of the first photoresist layer 410, which are other than an area in contact with the conductive connector 220 may be in contact with the first encapsulation layer 210. The conductive pad 442 may be buried in the first photoresist layer 410, and the conductive pad 442 may be exposed to the lower surface of the first photoresist layer 410. For example, the first photoresist layer 410 does not cover a bottom surface of the conductive pad 442.

The insulating layer 420 may be arranged along a lower surface of the first photoresist layer 410. The conductive pattern 444 may be buried in the insulating layer 420. The conductive pattern 444 may include a plurality of horizontal patterns extending in the first horizontal direction (X direction) and/or the second horizontal direction (Y direction) and having different vertical levels from each other and a plurality of vertical vias connecting the plurality of horizontal patterns having different vertical levels from each other and extending in the vertical direction (Z direction). For convenience, the horizontal patterns having different vertical levels and the vertical vias are not shown in the drawings.

The second photoresist layer 430 may be arranged along a lower surface of the insulating layer 420. The external connection pad 446 may be buried in the second photoresist layer 430 and may be bonded to the external connection terminal 500. The external connection terminal 500 may include, for example, tin (Sn), lead (Pb), silver (Ag), copper (Cu), or a conductive material including a combination thereof. The external connection terminal 500 may be formed by, for example, using a solder ball. The external connection terminal 500 may connect the semiconductor package 10 to a circuit board, another semiconductor package, an interposer, or a combination thereof.

The external connection terminal 500 may be bonded to the external connection pad 446. The external connection pad 446 may electrically and physically connect the external connection terminal 500 to the conductive pattern 444.

The first photoresist layer 410 and the second photoresist layer 430 may include, for example, a photo acid generator (PAG) and a photo base generator (PBG). The PAG needs to have a high light efficiency to generate an acid at a low light exposure dose. The PBG needs to have a lower light efficiency than the PAG to generate a base at a high light exposure dose.

The insulating layer 420 may include, for example, an inorganic insulating material, an organic insulating material, or a combination thereof. The inorganic insulating material may include, for example, a silicon oxide, a silicon nitride, or a combination thereof. The organic insulating material may include, for example, polyimide, epoxy resin, or a combination thereof.

The conductive pattern 444, the conductive pad 442, and the external connection pad 446 may include a conductive material which may include copper (Cu), gold (Au), silver (Ag), nickel (Ni), tungsten (W), aluminum (Al), or a combination thereof. In some embodiments, the conductive pattern 444, the conductive pad 442, and the external connection pad 446 may further include a barrier material for preventing diffusion of the conductive materials to the outside of the conductive pattern 444, the conductive pad 442, and the external connection pad 446. The barrier material may include, for example, titanium (Ti), tantalum (Ta), titanium nitride (TiN), tantalum nitride (TaN), or a combination thereof.

The bonding wire 310 may connect the printed circuit board 400 to the plurality of semiconductor chips 110. The bonding wire 310 may include a metal such as gold, silver, copper, platinum, or an alloy thereof, which may be welded to a die pad by ultrasonic energy and/or heat. The bonding wire may have a length of hundreds of micrometers (um).

The bonding wire 310 may be formed to extend in the vertical direction (Z direction) as illustrated in FIG. 1. In some embodiments, all or some sections of the bonding wire 310 may include an inclined section; however, the bonding wire 310 may generally extend in the vertical direction (Z direction) and directly connect the semiconductor chip 110 to the printed circuit board 400.

One end of the bonding wire 310 may be a first convex portion 311. In the process of bonding each bonding wire 310 to the chip pad 114 of the semiconductor chip 110, the bonding wire 310 may be compressed onto the chip pad 114. In this regard, an end of the bonding wire 310 may be formed as the first convex portion 311 due to the physical and thermal pressure. Or, in the process of bonding the bonding wire 310 to the semiconductor chip 110, for effective bonding, the first convex portion 311 may be included when the bonding wire 310 is formed. The first convex portion 311 may be integrated with the bonding wire 310 and may not form an interface with the bonding wire 310.

One end of the bonding wire 310 may be connected to the chip pad 114 of the semiconductor chip 110, and another end opposite thereto may be connected to the printed circuit board 400. The bonding wire 310 may extend as a straight line towards the conductive connector 220. As illustrated in FIG. 1, a plurality of bonding wires 310 may have different lengths from each other in the vertical direction (Z direction). The length of each bonding wire 310 may vary according to a distance between the printed circuit board 400 and the semiconductor chip 110.

The bonding wire 310 may include a conductive material which may include copper (Cu), gold (Au), silver (Ag), nickel (Ni), tungsten (W), aluminum (Al), or a combination thereof. In particular, the bonding wire 310 may include copper (Cu) and/or gold (Au). In some embodiments, the bonding wire 310 may further include a barrier material to prevent diffusion of the conductive material to the outside of the bonding wire 310. The barrier material may include, for example, titanium (Ti), tantalum (Ta), titanium nitride (TiN), tantalum nitride (TaN), or a combination thereof.

In some embodiments, the bonding wire 310 may have a diameter of about 0.7 mm to about 1 mm in a plan view. However, aspects of the inventive concept are not limited to thereto.

In some embodiments, the conductive connector 220 may include tin (Sn), indium (In), bismuth (Bi), antimony (Sb), copper (Cu), silver (Ag), zinc (Zn), lead (Pb), and/or an alloy thereof. A melting point of a material included in the conductive connector 220 may need to be lower than a melting point of a conductive material included in the bonding wire 310.

The conductive pad 442 of the printed circuit board 400 may be aligned with the conductive connector 220 and may electrically connect the bonding wire 310 to the printed circuit board 400 through the conductive connector 220.

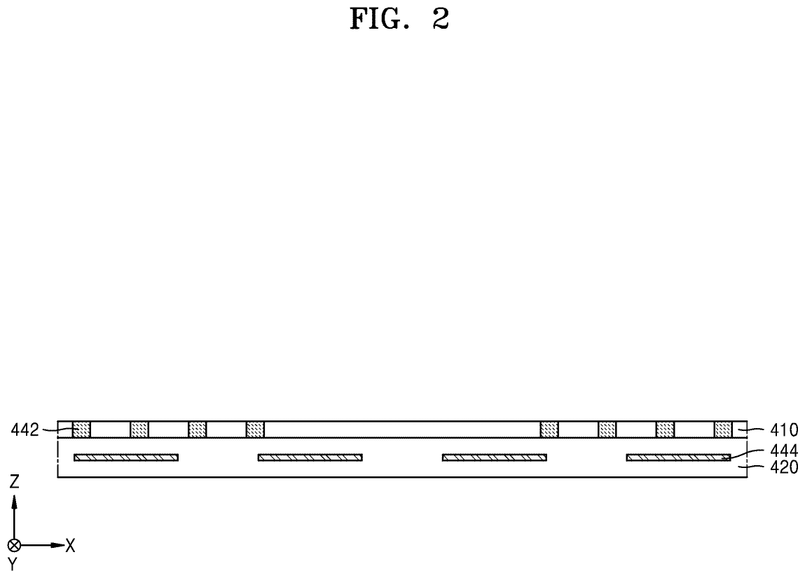

FIGS. 2 to 9 are each a cross-sectional view partially illustrating a process of manufacturing the semiconductor package 10 according to an embodiment. The semiconductor package may be the semiconductor package 10 described in relation to FIG. 1.

Referring to FIG. 2, some components of the printed circuit board may be prepared first. The insulating layer 420 in which the conductive pattern 444 is buried may be prepared, and the first photoresist layer 410 having a conformal thickness may be prepared on the insulating layer 420. The first photoresist layer 410 may include the conductive pad 442. The conductive pattern 444 may include a plurality of horizontal patterns extending in the first horizontal direction (X direction) and/or the second horizontal direction (Y direction) and having different vertical levels from each other and a plurality of vertical vias connecting the plurality of horizontal patterns having different vertical levels from each other and extending in the vertical direction (Z direction). For convenience, the horizontal patterns having different vertical levels and the vertical vias are not shown in the drawings.

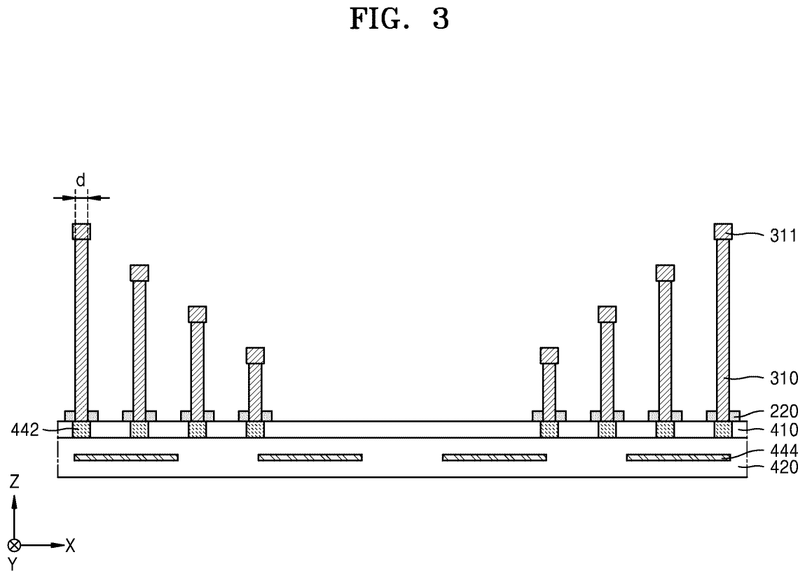

Referring to FIG. 3, on the first photoresist layer 410, the conductive connector 220 may be formed to be aligned with the conductive pad 442, and the bonding wire 310 extending in the vertical direction (Z direction) may be formed.

The horizontal cross-section of the bonding wire 310 may be, for example, circular. A diameter d of the horizontal cross-section of the bonding wire 310 may be in a range from about 0.7 mm to about 1 mm. However, aspects of the inventive concept are not limited thereto, and the horizontal cross-section of the bonding wire 310 may be tetragonal or polygonal.

The bonding wire 310 may include, for example, copper (Cu) and/or gold (Au). As illustrated in FIG. 3, the bonding wires 310 may have different lengths from each other in the vertical direction (Z direction).

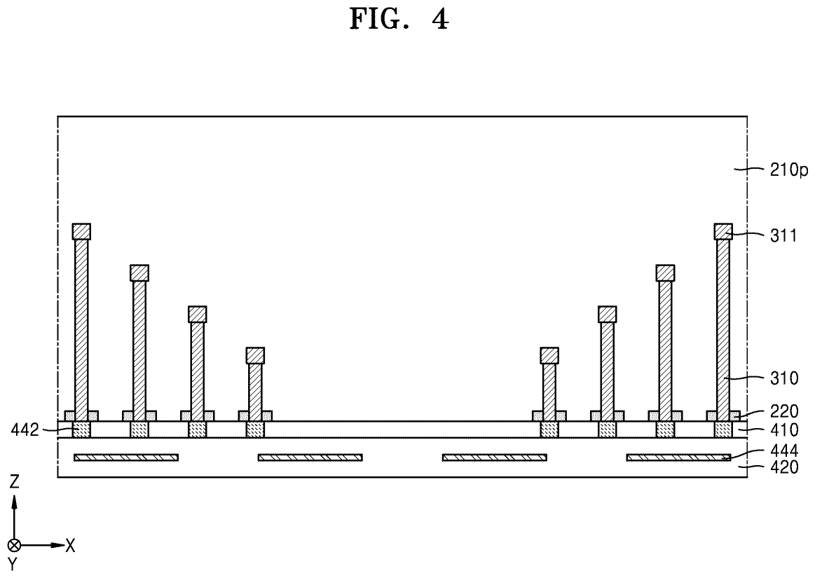

Referring to FIG. 4, a preliminary first encapsulation layer 210p molding all of the first photoresist layer 410, the conductive connector 220, and the bonding wire 310 may be formed.

The preliminary first encapsulation layer 210p may be formed to be thick enough to cover the bonding wire 310 extending farthest from the insulating layer 420 in the vertical direction (Z direction).

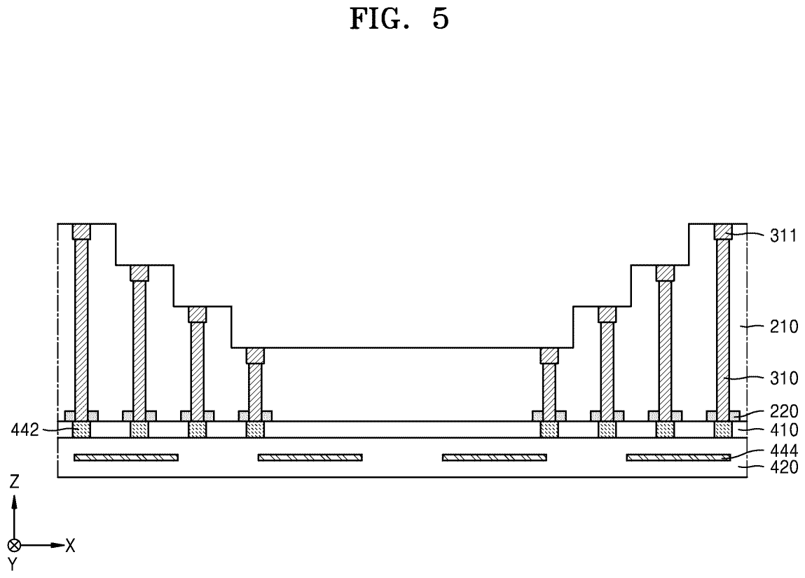

Referring to FIG. 5, by partially removing the preliminary first encapsulation layer 210p, the first encapsulation layer 210 may be formed. The first encapsulation layer 210 may be left to have an upper surface in a stepped shape. The first encapsulation layer 210 may be formed by using a grinding process.

With respect to the preliminary first encapsulation layer 210p formed in a bulk shape, the grinding process may be performed until the upper surface of the first convex portion 311, which is the uppermost portion of the bonding wire 310, is coplanar with the upper surface of the first encapsulation layer 210. The first encapsulation layer 210 completed to have the bonding wires 310 having different lengths from each other in the vertical direction (Z direction) may be left in a stepped shape.

In some embodiments, the coefficient of thermal expansion of the material included in the first encapsulation layer 210 may be about 10 ppm/° C. to about 15 ppm/° C. In some embodiments, the thermal conductivity of the material included in the first encapsulation layer 210 may be about 1.8 W/mK to about 3 W/mK.

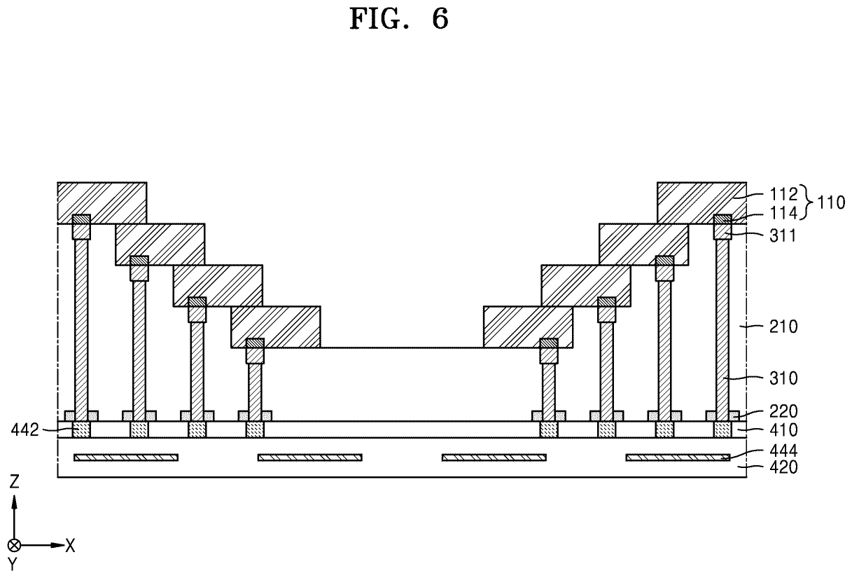

Referring to FIG. 6, in the result of FIG. 5, the semiconductor chip 110 may be attached such that the first convex portion 311 of the bonding wire 310 is in contact with the chip pad 114.

The semiconductor chip 110 may further include the body 112 and the chip pad 114. Although it is not shown in the drawings, an insulating adhesive layer having a thickness of tens of micrometers may be included in the lower portion of the semiconductor chip 110. The body 112 may include a semiconductor material, and the chip pad 114 may be in contact with the first convex portion 311.

As the upper portion of the first encapsulation layer 210 has a stepped shape (see FIG. 5), the semiconductor chips 110 may be arranged in a stepped manner.

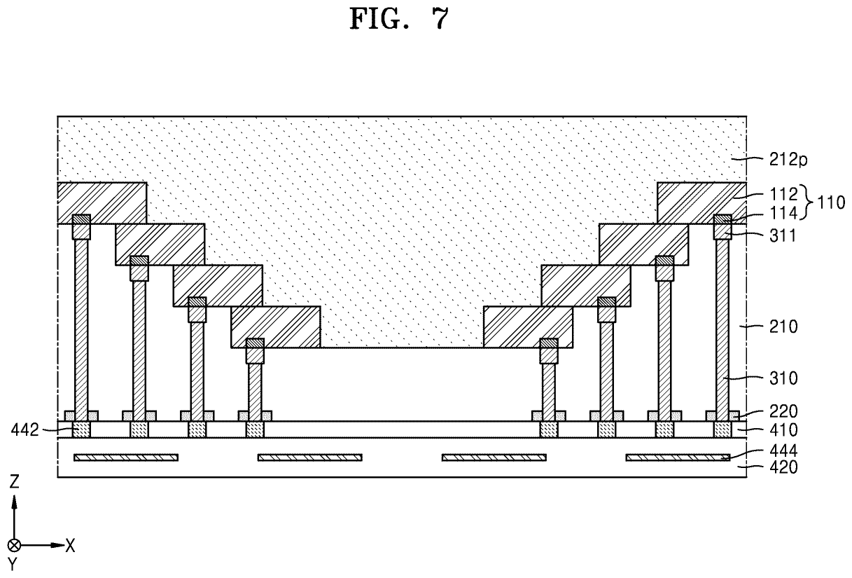

Referring to FIG. 7, a preliminary second encapsulation layer 212p may be formed to cover the upper surfaces and the lateral surfaces of the semiconductor chips 110 and the exposed upper surface of the first encapsulation layer 210.

The preliminary second encapsulation layer 212p may be formed in a bulk shape.

The preliminary second encapsulation layer 212p may include a material different from a material of the first encapsulation layer 210. In some embodiments, the coefficient of thermal expansion of the material included in the preliminary second encapsulation layer 212p may be about 2.5 ppm/° C. to about 6 ppm/° C. In some embodiments, the thermal conductivity of the material included in the preliminary second encapsulation layer 212p may be about 1.5 W/mK to about 2 W/mK.

As the preliminary second encapsulation layer 212p includes a different material from the first encapsulation layer 210, the preliminary second encapsulation layer 212p may have a different thermal expansivity from the first encapsulation layer 210, and as a result, when a warpage occurs at a semiconductor package, the mechanical stability of the semiconductor package may be more secured, as compared to the case where a single encapsulation material is used.

However, in some embodiments, the preliminary second encapsulation layer 212p may include the same material as the first encapsulation layer 210. Whether the preliminary second encapsulation layer 212p includes the same material as the first encapsulation layer 210 does not limit the inventive concept.

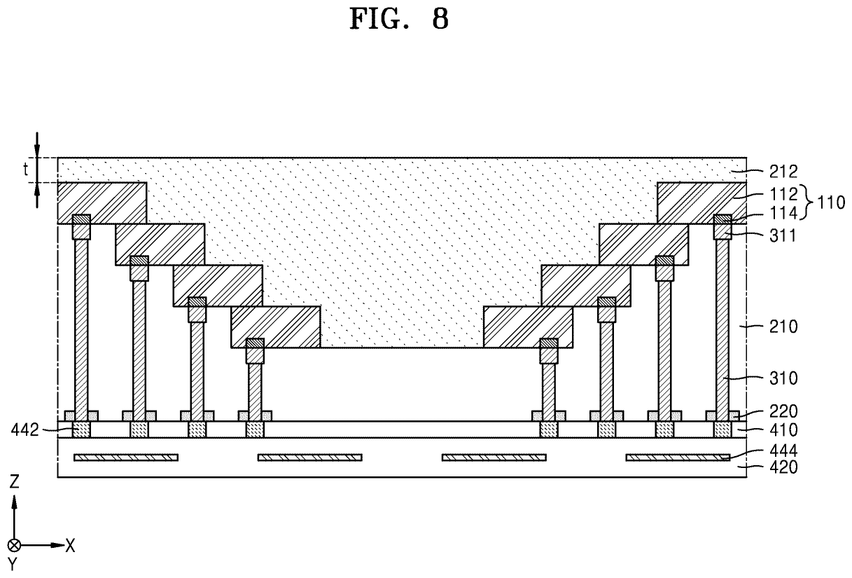

Referring to FIG. 8, by partially removing the preliminary second encapsulation layer 212p, the second encapsulation layer 212 may be formed. Unlike the first encapsulation layer 210, the vertical level of the upper surface of the second encapsulation layer 212 may be the same in all areas.

In some embodiments, a thickness t between the upper surface of the semiconductor chip 110 arranged at the highest vertical level, from among the plurality of semiconductor chips 110, and the upper surface of the second encapsulation layer 212 may be in a range from about 50 um to about 70 um.

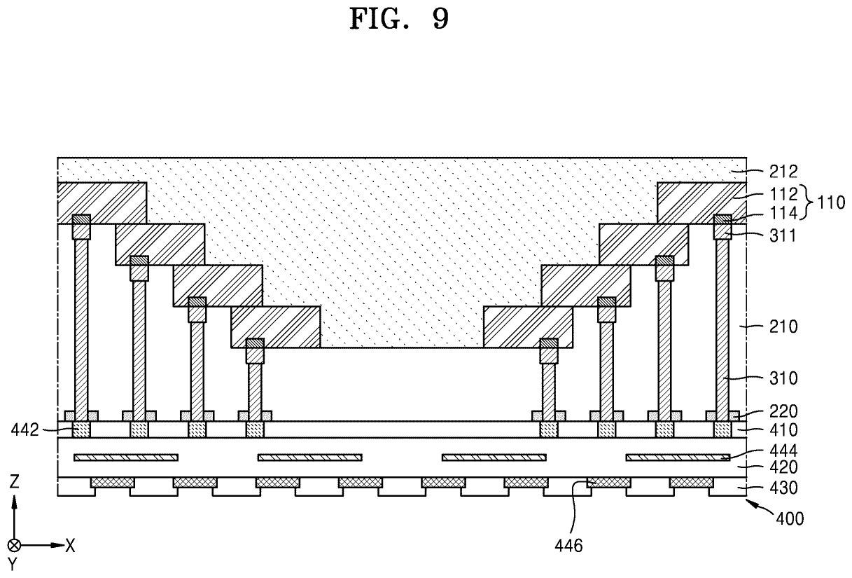

Referring to FIG. 9, in the result of FIG. 8, the second photoresist layer 430 and the external connection pad 446 may be formed on the lower surface of the insulating layer 420.

In the result of FIG. 9, the external connection terminal 500 may be attached onto the external connection pad 446 exposed to (i.e., not covered by) the second photoresist layer 430. In this regard, the external connection terminal may be, for example, a solder ball or a bump. By attaching the external connection terminal 500, the semiconductor package 10 of FIG. 1 may be obtained.

In the semiconductor package 10 according to aspects of the inventive concept, the bonding wire 310 perpendicular to the substrate may be formed first, and then the preliminary first encapsulation layer 210p in a bulk shape may be formed. Through the grinding process, the upper surface of the bonding wire 310 may be exposed, which is connected to the semiconductor chip 110. By forming the second encapsulation layer 212 filling the upper space of the semiconductor chip 110, the semiconductor package 10 of FIG. 1 may be obtained.

In the semiconductor package 10, as the vertical bonding wire 310 is formed before the first encapsulation layer 210 is formed, the sagging of the vertical bonding wire 310 may be prevented. Accordingly, even when vertical wires having a relatively small wire diameter are employed, the high reliability and stability of the semiconductor package according to aspects of the inventive concept may be maintained.

Furthermore, as the semiconductor package 10 includes molding materials of different kinds, the semiconductor package 10 may have improved thermal stability, as compared to the case where a single molding material is included.

While aspects of the inventive concept have been particularly shown and described with reference to embodiments thereof, it will be understood that various changes in form and details may be made therein without departing from the spirit and scope of the following claims.

What is claimed is:

1. A semiconductor package comprising:
a printed circuit board;
a plurality of semiconductor chips arranged apart from the printed circuit board in a vertical direction;
a plurality of bonding wires, wherein a first end of each of the bonding wires is in contact with the printed circuit board, and a second end, which is opposite to the first end, is in contact with a chip pad included in each of the plurality of semiconductor chips;
a first encapsulation layer filling spaces between lower surfaces of the plurality of semiconductor chips and an upper surface of the printed circuit board and spaces between the plurality of bonding wires; and
a second encapsulation layer covering an upper surface of the first encapsulation layer and the plurality of semiconductor chips and including a flat upper surface arranged apart from the upper surface of the printed circuit board by a same height in all areas.

2. The semiconductor package of claim 1, wherein a material included in the first encapsulation layer is different from a material included in the second encapsulation layer.

3. The semiconductor package of claim 1, wherein a coefficient of thermal expansion of a material included in the first encapsulation layer is in a range from 10 ppm/° C. to 15 ppm/° C.

4. The semiconductor package of claim 1, wherein a coefficient of thermal expansion of a material included in the second encapsulation layer is in a range from 2.5 ppm/° C. to 6 ppm/° C.

5. The semiconductor package of claim 1, wherein a thermal conductivity of a material included in the first encapsulation layer is in a range from 1.8 W/mK to 3 W/mK.

6. The semiconductor package of claim 1, wherein a thermal conductivity of a material included in the second encapsulation layer is in a range from 1.5 W/mK to 2 W/mK.

7. The semiconductor package of claim 1, wherein the plurality of bonding wires extend perpendicular to the upper surface of the printed circuit board.

8. The semiconductor package of claim 1, wherein a wire diameter of each of the plurality of bonding wires is in a range from 0.7 mm to 1 mm.

9. The semiconductor package of claim 1, wherein some of the plurality of bonding wires have different lengths from each other.

10. The semiconductor package of claim 1, wherein the upper surface of the first encapsulation layer has a stepped shape.

11. The semiconductor package of claim 1, wherein the first end of each of the plurality of bonding wires vertically passes through a conductive connector, and the second end of each of the plurality of bonding wires has a convex shape.

12. The semiconductor package of claim 11, wherein a conductive pad included in the printed circuit board overlaps and is in contact with the conductive connector in the vertical direction.

13. The semiconductor package of claim 1, wherein a distance between an upper surface of a semiconductor chip arranged farthest from the printed circuit board, from among the plurality of semiconductor chips, and the upper surface of the second encapsulation layer is from 50 um to 70 um.

14. A semiconductor package comprising:
a printed circuit board including a first surface and a second surface opposite to the first surface;
a plurality of semiconductor chips stacked in a stepped manner in a first horizontal direction at a vertical level higher than the first surface of the printed circuit board;
a plurality of bonding wires connecting the plurality of semiconductor chips to the first surface of the printed circuit board in a vertical direction and each overlapping a conductive pad included in the printed circuit board in the vertical direction;
a first encapsulation layer filling spaces between lower surfaces of the plurality of semiconductor chips and an upper surface of the printed circuit board and spaces between the plurality of bonding wires;
a second encapsulation layer covering upper surfaces and lateral surfaces of the plurality of semiconductor chips stacked in the stepped manner, filling a space on the first encapsulation layer, and including a flat upper surface arranged apart from the first surface by a same height in all areas; and
an external connection terminal attached onto the second surface of the printed circuit board,
wherein the second encapsulation layer is in contact with the first encapsulation layer in at least some areas and is arranged apart from the first encapsulation layer with the plurality of semiconductor chips arranged therebetween in the other areas that are not in contact with the first encapsulation layer, and
the first encapsulation layer and the second encapsulation layer include different materials from each other.

15. The semiconductor package of claim 14, wherein a coefficient of thermal expansion of a material included in the first encapsulation layer is in a range from 10 ppm/° C. to 15 ppm/° C., and a coefficient of thermal expansion of a material included in the second encapsulation layer is in a range from 2.5 ppm/° C. to 6 ppm/° C.

16. The semiconductor package of claim 14, wherein a thermal conductivity of a material included in the first encapsulation layer is in a range from 1.8 W/mK to 3 W/mK, and a thermal conductivity of a material included in the second encapsulation layer is in a range from 1.5 W/mK to 2 W/mK.

17. The semiconductor package of claim 14, wherein the plurality of bonding wires comprise at least one selected from copper (Cu), gold (Au), and a combination thereof, and
a wire diameter of each of the plurality of bonding wires is in a range from 0.7 mm to 1 mm.

18. The semiconductor package of claim 14, wherein each of the plurality of semiconductor chips is connected to at least one bonding wire.

19. The semiconductor package of claim 14, wherein a distance between an upper surface of a semiconductor chip arranged farthest from the first surface of the printed circuit board, from among the plurality of semiconductor chips, and the upper surface of the second encapsulation layer is in a range from 50 um to 70 um.

20. A semiconductor package comprising:
a printed circuit board including an upper surface and a lower surface, and arranged at a vertical level lower than a plurality of first semiconductor chips and a plurality of second semiconductor chips;
at least one first semiconductor chip stack in which the plurality of first semiconductor chips are stacked in a stepped manner in a first horizontal direction, wherein the first horizontal direction is a direction horizontal to surfaces of the plurality of first semiconductor chips and a direction in which the plurality of first semiconductor chips are stacked;
at least one second semiconductor chip stack in which the plurality of second semiconductor chips are stacked in the stepped manner in a reverse first horizontal direction which is opposite to the first horizontal direction, wherein the reverse first horizontal direction is a direction horizontal to the plurality of second semiconductor chips and a direction in which the plurality of second semiconductor chips are stacked;
a first encapsulation layer sealing a space between the upper surface of the printed circuit board and the at least one first semiconductor chip stack and the at least one second semiconductor chip stack;
a plurality of bonding wires arranged within the first encapsulation layer and connecting each of the plurality of first semiconductor chips and each of the plurality of second semiconductor chips to the printed circuit board in a vertical direction;
a second encapsulation layer covering upper surfaces and lateral surfaces of the at least one first semiconductor chip stack and the at least one second semiconductor chip stack, and an upper surface of the first encapsulation layer, the second encapsulation layer including a material having a different coefficient of thermal expansion than a material included in the first encapsulation layer; and
an external connection terminal attached onto the lower surface of the printed circuit board,
wherein a wire diameter of each of the plurality of bonding wires is in a range from 0.7 mm to 1 mm, and
a distance between an upper surface of the second encapsulation layer and the first and second semiconductor chip stacks is in a range from 50 um to 70 um.
